(19) United States
(12) Patent Application Publication
(10) Pub. No.: US 2025/0220850 A1
(43) Pub. Date: Jul. 3, 2025

(54) COOLING DEVICE

(71) Applicant: MITSUBISHI HEAVY INDUSTRIES, LTD., Tokyo (JP)

(72) Inventors: Tsutomu Kawamizu, Tokyo (JP); Hiroki Matsuda, Tokyo (JP)

(73) Assignee: MITSUBISHI HEAVY INDUSTRIES, LTD., Tokyo (JP)

(21) Appl. No.: 18/850,893

(22) PCT Filed: Oct. 28, 2022
(86) PCT No.: PCT/JP2022/040467

§ 371 Date: Sep. 25, 2024

(30) Foreign Application Priority Data
Mar. 31, 2022 (JP) 2022-060220

(51) Int. Cl. H05K 7/20

(52) U.S. Cl. CPC H05K 7/20254; H05K 7/20263

(57) ABSTRACT

A cooling device of the present disclosure is a cooling device that cools a plurality of semiconductor components, which are mounted on a front surface of a substrate and are arranged in a first direction, the cooling device including a base attached to a rear surface of the substrate, a bottom plate disposed apart from the base to form a flow path through which a refrigerant flows between the bottom plate and the base, and a cooling body disposed in the flow path, in which an introduction port, through which the refrigerant is guided into the flow path from a direction facing the rear surface, is formed in a central portion of the bottom plate in the first direction, and a flow path cross sectional area of the flow path at the introduction port is smaller than the flow path cross sectional areas on both sides of the flow path in the first direction.

### TECHNICAL FIELD

The present disclosure relates to a cooling device.

Priority is claimed on Japanese Patent Application No. 2022-060220 filed in Japan on Mar. 31, 2022, the contents of which are incorporated herein by reference.

### BACKGROUND ART

As a device for cooling a semiconductor component (chip), for example, a device disclosed in Patent Document 1 is known. In the device disclosed in Patent Document 1, a cooling water passage through which cooling water flows is formed between a plurality of semiconductor modules. It is considered that the cooling water is guided from one end of the cooling water passage in the lateral direction and the semiconductor modules can be sequentially cooled.

### CITATION LIST

### Patent Document

Patent Document 1: Japanese Unexamined Patent Publication No. 2006-203138

### SUMMARY OF INVENTION

### Technical Problem

Meanwhile, in a case where the plurality of semiconductor components are mounted as described above, the heat generation of each semiconductor component is superimposed, so that a temperature in a central portion of the plurality of semiconductor components is likely to be high. Therefore, as in Patent Document 1, in a configuration in which the cooling water is allowed to flow sequentially in the lateral direction from one end of a cooling water passage, there is a concern that a cooling effect is insufficient in the central portion.

The present disclosure has been made in order to solve the above-described problems, and an object of the present disclosure is to provide a cooling device that exhibits a higher cooling effect.

### Solution to Problem

In order to solve the above-described problems, according to the present disclosure, there is provided a cooling device that cools a plurality of semiconductor components, which are mounted on a front surface of a substrate and are arranged in a first direction, the cooling device including a base attached to a rear surface of the substrate, a bottom plate disposed apart from the base to form a flow path through which a refrigerant flows between the bottom plate and the base, and a cooling body disposed in the flow path, in which an introduction port, through which the refrigerant is guided into the flow path from a direction facing the rear surface, is formed in a central portion of the bottom plate in the first direction, and a flow path cross sectional area of the flow path at the introduction port is smaller than flow path cross sectional areas on both sides of the flow path in the first direction.

### Advantageous Effects of Invention

According to the present disclosure, it is possible to provide a cooling device that exhibits a higher cooling effect.

### BRIEF DESCRIPTION OF DRAWINGS

FIG. 1 is a cross-sectional view showing the configuration of a cooling device and a substrate according to a first embodiment of the present disclosure.

FIG. 2 is a cross-sectional view taken along the line II-II in FIG. 1.

FIG. 3 is a cross-sectional view taken along the line III-III of FIG. 1.

FIG. 4 is a cross-sectional view taken along the line IV-IV in FIG. 1.

FIG. 5 is a cross-sectional view showing the configuration of a cooling device and a substrate according to a modification example of the first embodiment of the present disclosure.

FIG. 6 is a cross-sectional view showing the configuration of a cooling device and a substrate according to a second embodiment of the present disclosure.

FIG. 7 is a cross-sectional view showing the configuration of a cooling device and a substrate according to a modification example of the second embodiment of the present disclosure.

FIG. 8 is a diagram showing a first modification example common to each of the embodiments of the present disclosure, and is a schematic view showing a configuration of an introduction port.

FIG. 9 is a diagram showing a second modification example common to each of the embodiments of the present disclosure, and is a view corresponding to the cross-sectional view taken along the line IV-IV in FIG. 1.

FIG. 10 is a cross-sectional view showing the configuration of a cooling device and a substrate according to a third embodiment common to each of the embodiments of the present disclosure.

### DESCRIPTION OF EMBODIMENTS

### First Embodiment

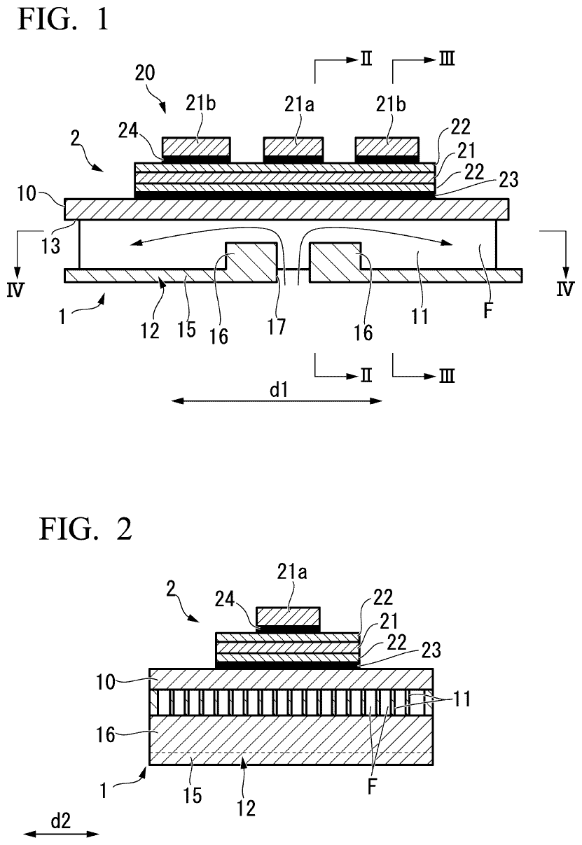

Hereinafter, a substrate 2 and a cooling device 1 according to a first embodiment of the present disclosure will be described with reference to FIGS. 1 to 4. The cooling device 1 is for cooling semiconductor components 20 mounted on the substrate 2 with a liquid refrigerant.

### (Configuration of Substrate)

As shown in FIG. 1, the substrate 2 includes a substrate main body 21, copper patterns 22, and bonding materials 23 and 24.

The substrate main body 21 is formed in a plate shape of, for example, a glass epoxy resin, a bakelite resin, or the like. The copper pattern 22 is vapor-deposited on each of a front surface and a rear surface of the substrate main body 21. A desired printed wiring line is formed on the copper patterns 22 by etching. The bonding material 24 is provided to fix the semiconductor components 20 to the copper pattern 22.

A plurality (three in this example) of the semiconductor components 20 are disposed on the substrate 2. The semiconductor components 20 are electrically connected to the above-described copper patterns 22. The semiconductor components 20 are, for example, a power transistor or a power FET, and generate heat due to an internal resistance accompanying an operation thereof. The semiconductor components 20 are arranged on the substrate 2 at intervals from each other in a first direction d1. In the following description, among the three semiconductor components 20, the semiconductor component 20 located in the central portion of the first direction d1 may be referred to as a first semiconductor component 21a, and a pair of semiconductor components 20 located on both sides thereof may be referred to as second semiconductor components 21b.

### (Configuration of Cooling Device)

Next, a configuration of the cooling device 1 will be described. As shown in FIG. 1, the cooling device 1 includes a base 10, fins 11, and a bottom plate 12. The base 10, the fins 11, and the bottom plate 12 are formed of a metal material having good thermal conductivity such as aluminum or copper. The cooling device 1 can also be formed by an Additive Manufacturing (AM) method. In addition, the base 10, the fins 11, and the bottom plate 12 may be integrally formed, or only the bottom plate 12 may be attachable to and detachable from the base 10 and the fins 11. In this case, it is desirable that a leakage prevention member such as an O-ring is disposed on a bonding surface between the bottom plate 12 and the fin 11.

The base 10 is fixed to a rear surface (that is, a surface facing a side opposite to the front surface on which the semiconductor components 20 are mounted) of the above-described substrate 2 by the bonding material 23. The base 10 has a plate shape having a larger area than the substrate 2.

A plurality of fins 11 (cooling bodies) are provided on a rear surface 13 of the base 10. Each of the fins 11 protrudes in a direction apart from the base 10. More specifically, as shown in FIG. 4, the fins 11 extend in the second direction d2 orthogonal to the first direction d1 along the rear surface 13 of the base 10 and are arranged at intervals in the first direction d1. As a result, a flow path F through which a refrigerant flows is formed between the fins 11. In addition, a pair of side walls 14 are provided on both sides in the first direction d1.

Again, as shown in FIG. 1, the above-described fins 11 are supported between the base 10 and the bottom plate 12. The bottom plate 12 has a bottom plate main body 15 and thick wall portions 16. The bottom plate main body 15 has a plate shape which is disposed apart from the base 10 by the amount of the flow path F. The bottom plate main body 15 extends in the first direction d1 and the second direction d2. The thickness of the bottom plate main body 15 is constant over the entire region.

An introduction port 17 for guiding the refrigerant from the outside into the flow path F is formed in a central portion of the bottom plate main body 15 in the first direction d1 (that is, a central portion in the first direction d1 in a region where the plurality of semiconductor components 20 are disposed: a region overlapping the first semiconductor component 21a). The introduction port 17 is a rectangular opening extending in the second direction d2 (see FIG. 4). The refrigerant is introduced in a direction toward the base 10 from the bottom plate main body 15 through the introduction port 17. In addition, alcohol or the like is suitably used as the refrigerant in addition to low-temperature water.

The thick wall portions 16 are provided on a surface of the bottom plate 12 facing a side of the flow path F and on both sides of the introduction port 17 in the first direction d1. The thick wall portion 16 has a thickness larger than that of the bottom plate main body 15. The thick wall portions 16 are formed one by one on both sides of the first direction d1 with the introduction port 17 interposed therebetween. The thick wall portions 16 extend to a region that overlaps at least the first semiconductor component 21a in the first direction d1. On the other hand, in the first direction d1, the thick wall portions 16 do not overlap the second semiconductor component 21b. The thickness of the thick wall portion 16 is constant over the entire region of the first direction d1.

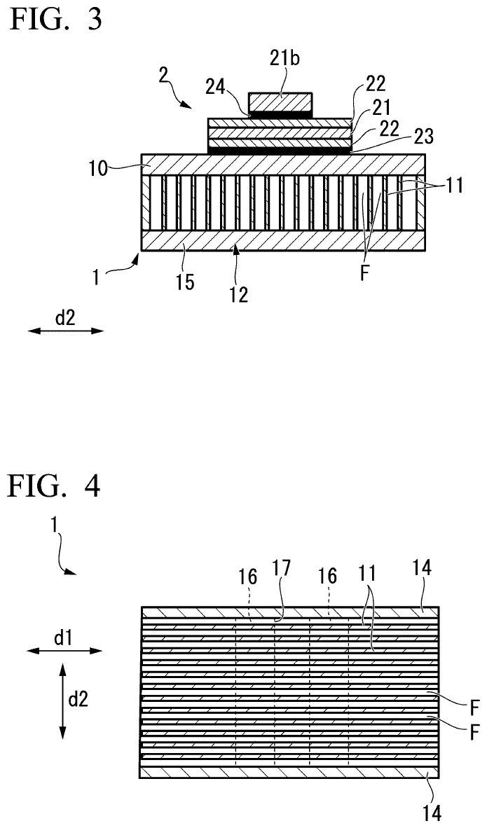

The thick wall portions 16 are formed, so that the flow path cross sectional area of the flow path F is changed as shown in FIG. 2 and FIG. 3. Specifically, as shown in FIG. 2, a flow path cross sectional area of a region around the introduction port 17 in which the thick wall portion 16 is formed is small as compared to a flow path cross sectional area of a region in which the thick wall portion 16 is not formed, that is, a region on both end sides in the first direction d1. That is, the flow path cross sectional area of the region corresponding to the first semiconductor component 21a is smaller than the flow path cross sectional area of the region corresponding to the second semiconductor component 21b.

### (Operation and Effect)

In a case where a current flows through the above-described semiconductor components 20, the semiconductor components 20 generate heat in association with internal resistance. In a case in which it is assumed that the heat generation amounts of the plurality of semiconductor components 20 are equal to each other, in the periphery of the first semiconductor component 21a among the above-described three semiconductor components 20, the heat generation is superimposed by receiving the influence of the second semiconductor component 21b. As a result, in a case where the cooling conditions are the same, the first semiconductor component 21a is likely to be at a higher temperature than the second semiconductor component 21b. Therefore, in the present embodiment, the above-described configuration is adopted.

With the above configuration, the introduction port 17 is formed in the central portion in the first direction d1, that is, in the region corresponding to the first semiconductor component 21a. As a result, the refrigerant having the lowest temperature in the initial stage can be supplied to the first semiconductor component 21a. As a result, it is possible to preferentially and efficiently cool the first semiconductor component 21a that is affected by the influence of the superimposed heat generation. Therefore, the temperature difference between the first semiconductor component 21a and the second semiconductor component 21b is eliminated, and it is possible to significantly reduce the possibility that each semiconductor component 20 thermally runs away or is damaged.

Further, with the above-described configuration, since the flow path cross sectional area of the flow path F at the introduction port 17 is smaller than the flow path cross sectional area of the flow path F on both sides of the first direction d1, it is possible to increase the flow velocity of the refrigerant around the introduction port 17. As a result, it is possible to further improve the cooling effect on the first semiconductor component 21a located directly above the introduction port 17.

In addition, with the above-described configuration, the introduction port 17 is a rectangular opening extending in the second direction d2. As a result, the refrigerant is uniformly supplied from the introduction port 17 to the flow path F over the entire region in the second direction d2. In other words, the refrigerant is supplied to the flow path F in the second direction d2 without bias. As a result, the refrigerant is supplied to each semiconductor component 20 without unevenness, and thus it is possible to further increase the cooling effect on these semiconductor components 20.

In addition, with the above-described configuration, it is possible to change the flow path cross sectional area of the flow path F with a simple configuration only by forming the thick wall portions 16. In particular, in a case where the cooling device 1 is integrally formed by the AM forming method described above, it is possible to significantly simplify a manufacturing process. As a result, it is possible to reduce the manufacturing costs and the maintenance costs of the cooling device 1.

Further, with the above-described configuration, it is possible to efficiently cool the respective semiconductor components 20 using the fins 11 as the cooling body. In addition, since the flow direction of the refrigerant is defined only in the first direction d1 by the fins 11, the stagnation or the back flow of the refrigerant is suppressed, so that it is possible to more efficiently and stably cool each semiconductor component 20.

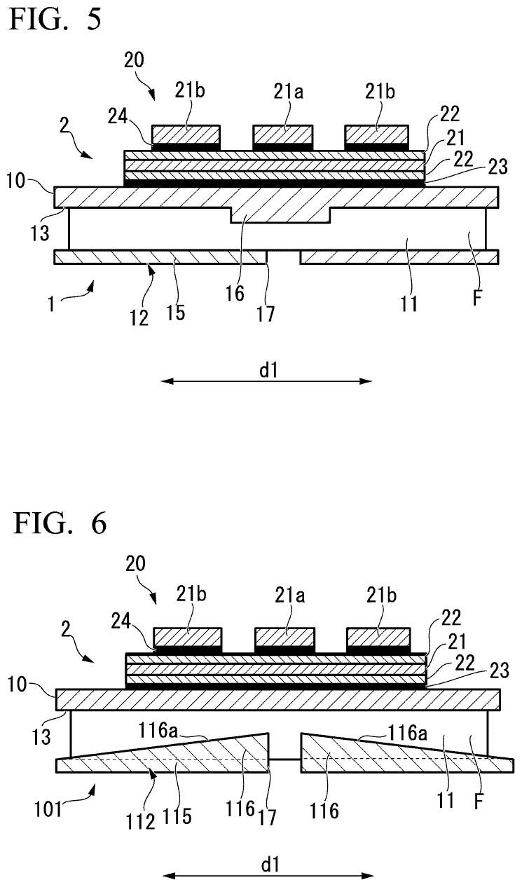

The first embodiment of the present disclosure has been described above. In addition, various changes or modifications can be made to the above configuration without departing from the scope of the present disclosure. For example, in the first embodiment described above, an example is described in which the thick wall portions 16 are formed on the bottom plate 12. However, as shown as a modification example in FIG. 5, the thick wall portions 16 may be formed in a region facing the introduction port 17 on the rear surface 13 (surface facing the side of the flow path F) of the base 10. In addition, the thick wall portions 16 may be provided in at least one of the bottom plate 12 or the base 10. In other words, each of the thick wall portions 16 may be formed on both the bottom plate 12 and the base 10. In this case, it is desirable that the thickness of the thick wall portion 16 is appropriately set such that the cooling effect of the refrigerant is applied to the first semiconductor component 21a.

### Second Embodiment

Next, a cooling device 101 according to a second embodiment of the present disclosure will be described with reference to FIG. 6. In addition, the same configurations as in the first embodiment described above are denoted by the same reference signs, and detailed descriptions thereof will be omitted. In the configuration of the cooling device 101, the configuration of the bottom plate 112 is different from that of the first embodiment, and the remaining configuration is the same as that of the first embodiment.

The bottom plate 112 includes a bottom plate main body 115 and slope portions 116. The bottom plate main body 115 has a plate shape which is disposed apart from the base 10 by the amount of the flow path F. The bottom plate main body 115 extends in the first direction d1 and the second direction d2. The thickness of the bottom plate main body 115 is constant over the entire region.

An introduction port 17 for guiding the refrigerant from the outside into the flow path F is formed in a central portion of the bottom plate main body 115 in the first direction d1 (that is, a central portion in the first direction d1 in a region where the plurality of semiconductor components 20 are disposed: a region overlapping the first semiconductor component 21a). The introduction port 17 is a rectangular opening extending in the second direction d2. The refrigerant is introduced in a direction toward the base 10 from the bottom plate main body 115 through the introduction port 17.

The slope portions 116 are provided on both sides of the introduction port 17 in the first direction d1. In a cross-sectional view from the second direction d2, the lengths of the slope portions 116 in a direction orthogonal to the first direction d1 and the second direction d2 are gradually reduced as being apart from the introduction port 17 on both sides in the first direction d1. That is, a surface (the inclined surface 116a) of the slope portion 116 facing a side of the base 10 extends in a direction apart from the base 10 as being apart from the introduction port 17, thereby being inclined with respect to the first direction d1.

The slope portion 116 is formed, so that the flow path cross sectional area of the flow path F is changed to be gradually increased as being toward both sides in the first direction d1 from the introduction port 17. Specifically, the flow path cross sectional area of the region around the introduction port 17 in which the slope portion 116 is formed is small as compared to a flow path cross sectional area of a region in which the slope portion 116 is not formed, that is, regions on both end sides in the first direction d1. That is, the flow path cross sectional area of the region corresponding to the first semiconductor component 21a is smaller than the flow path cross sectional area of the region corresponding to the second semiconductor component 21b.

With the above configuration, the introduction port 17 is formed in the central portion in the first direction d1, that is, in the region corresponding to the first semiconductor component 21a. As a result, the refrigerant having the lowest temperature in the initial stage can be supplied to the first semiconductor component 21a. As a result, it is possible to preferentially and efficiently cool the first semiconductor component 21a which is likely to be heated to a high temperature due to the influence of the superimposed heat generation. Therefore, the temperature difference between the first semiconductor component 21a and the second semiconductor component 21b is eliminated, and it is possible to significantly reduce the possibility that each semiconductor component 20 thermally runs away or is damaged.

Further, with the above-described configuration, the slope portion 116 is provided, thereby causing a state in which the step or the like is not formed in the flow path F from the introduction port 17 to both end portions in the first direction d1. As a result, the vortices or the stagnation likely to occur due to the step or the like is eliminated. Therefore, the pressure loss of the refrigerant flowing in the direction spaced away from the introduction port 17 is reduced. As a result, the flow of the refrigerant is further smoothed, and thus it is possible to further increase the cooling effect on each semiconductor component 20.

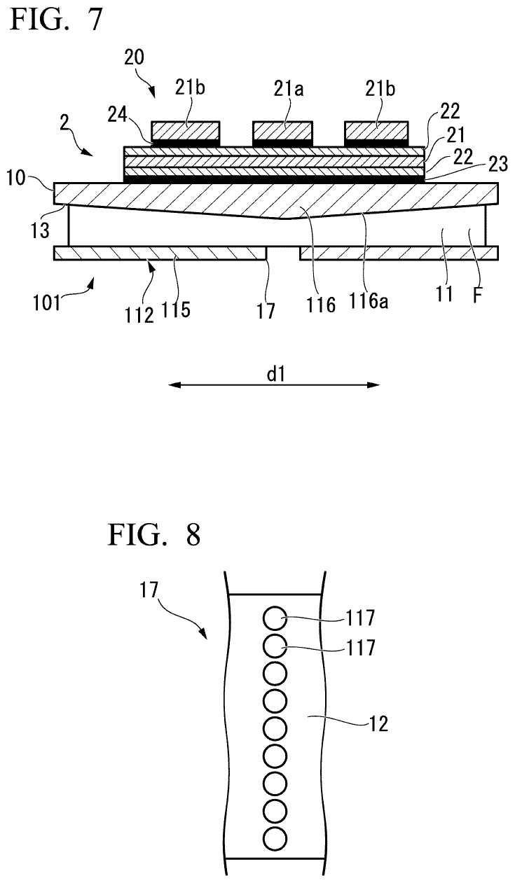

The second embodiment of the present disclosure has been described above. In addition, various changes or modifications can be made to the above configuration without departing from the scope of the present disclosure. For example, in the second embodiment described above, an example is described in which the slope portions 116 are formed on the bottom plate 112. However, as shown as a modification example in FIG. 7, the slope portion 116 may be formed in a region facing the introduction port 17 on the rear surface 13 of the base 10. In addition, the slope portion 116 may be provided on at least one of the bottom plate 112 or the base 10. In other words, each of the slope portion 116 may be formed on both the bottom plate 112 and the base 10. In this case, it is desirable that the thickness and the inclined angle of the slope portion 116 are appropriately set such that the cooling effect of the refrigerant is applied to the first semiconductor component 21a.

### Modification Examples Common to Each Embodiment

In each of the above-described embodiments, an example is described in which the introduction port 17 has a rectangular shape extending in the second direction d2. However, as shown in FIG. 8 as a modification example, the introduction port 17 may be formed of a plurality of the opening portions 117 arranged at intervals in the second direction d2. In the example of FIG. 8, the shape of the opening portion 117 is circular. In addition, the opening portion 117 may have a rectangular shape, a polygonal shape, or an elliptical shape. With this configuration, since the introduction port 17 is formed by the plurality of opening portions 117, the flow velocity of the refrigerant blown out from each opening portion 117 is increased as compared to a case where the introduction port 17 has one rectangular shape. As a result, it is possible to further increase the cooling effect on each semiconductor component 20.

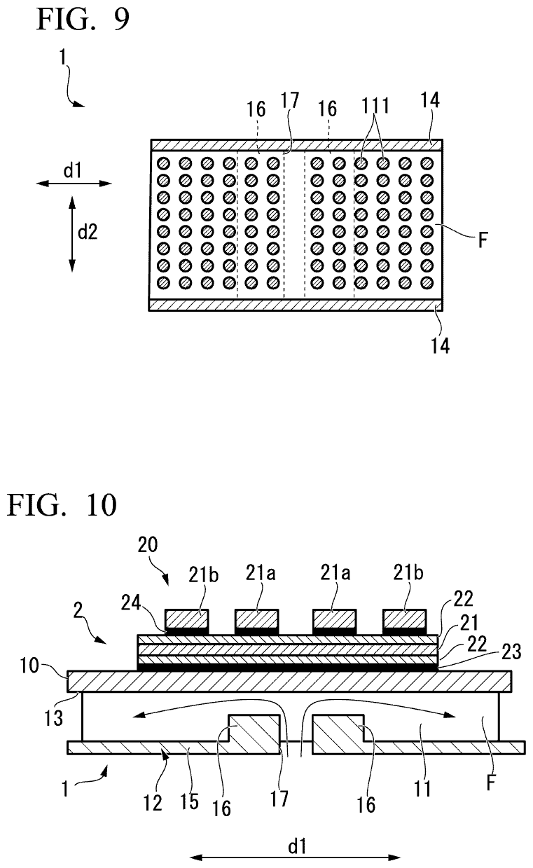

Further, in each of the above-described embodiments, an example is described in which the fins 11 are used as the cooling body. However, the aspect of the cooling body is not limited to the fin 11, and a plurality of pins 111 can also be used as shown in FIG. 9. The plurality of pins 111 are arranged in a lattice shape at intervals in the first direction d1 and the second direction d2. In addition, the cross-sectional shape of each pin 111 is circular. In addition, the cross-sectional shape of the pin 111 is not limited to the circular shape, and may be a rectangular shape, a polygonal shape, or an elliptical shape.

In addition, in each of the above-described embodiments, an example is described in which the substrate 2 has one first semiconductor component 21a and two second semiconductor components 21b. However, the aspect of the substrate 2 is not limited thereto, and a configuration shown in FIG. 10 can also be adopted. In the example of the same drawing, two first semiconductor components 21a are arranged at intervals in the first direction d1, and second semiconductor components 21b are further disposed one by one at intervals on both sides of the two first semiconductor components 21a. That is, a total of four semiconductor components 20 are disposed. In this case, it is desirable that the introduction port 17 of the cooling device 1 is located in a region between the two first semiconductor components 21a. As a result, it is possible to preferentially supply the initial low-temperature refrigerant to the two first semiconductor components 21a. As a result, it is possible to obtain the same operation and effect as in each of the above-described embodiments.

### Appendix

The cooling device 1 and 101 described in each embodiment is grasped, for example, as follows.

(1) A cooling device 1, 101 according to a first aspect is a cooling device 1, 101 that cools a plurality of semiconductor components 20, which are mounted on a front surface of a substrate 2 and are arranged in a first direction d1, the cooling device 1, 101 including: a base 10 attached to a rear surface 13 of the substrate 2, a bottom plate 12, 112 disposed apart from the base 10 to form a flow path F through which a refrigerant flows between the bottom plate 12, 112 and the base 10, and a cooling body disposed in the flow path F, in which an introduction port 17, through which the refrigerant is guided into the flow path F from a direction facing the rear surface 13, is formed in a central portion of the bottom plate 12, 112 in the first direction d1, and a flow path cross sectional area of the flow path F at the introduction port 17 is smaller than flow path cross sectional areas on both sides of the flow path F in the first direction d1.

With the above-described configuration, since the flow path cross sectional area of the flow path F at the introduction port 17 is smaller than the flow path cross sectional area of the flow path F on both sides of the first direction d1, it is possible to increase the flow velocity of the refrigerant around the introduction port 17. As a result, it is possible to improve the cooling effect on the semiconductor component 20 located directly above the introduction port 17.

(2) A cooling device 1, 101 according to a second aspect is the cooling device 1, 101 of (1), in which the introduction port 17 may extend in a second direction d2 orthogonal to the first direction d1.

With the above-described configuration, the refrigerant is supplied from the introduction port 17 uniformly over the entire region in the second direction d2, so that it is possible to further increase the cooling effect on each semiconductor component 20.

(3) A cooling device 1, 101 according to a third aspect is the cooling device 1, 101 of (1), in which the introduction port 17 may be formed of a plurality of opening portions 117 arranged at intervals in the second direction d2 orthogonal to the first direction d1.

With the above configuration, since the introduction port 17 is formed by the plurality of opening portions 117, the flow velocity of the refrigerant blown out from each opening portion 117 is increased. As a result, it is possible to further increase the cooling effect on each semiconductor component 20.

(4) A cooling device 1 according to a fourth aspect is the cooling device 1 according to any one aspect of (1) to (3), in a region, which is at least one of a surface of the bottom plate 12 facing a side of the flow path F and a surface of the base 10 facing the side of the flow path F and includes the introduction port 17, a thick wall portion 16 protruding from the bottom plate 12 toward a side of the base 10 is provided.

With the above-described configuration, it is possible to change the flow path cross sectional area of the flow path F with a simple configuration only by forming the thick wall portion 16. As a result, it is possible to reduce the manufacturing costs and the maintenance costs of the device.

(5) A cooling device 101 according to a fifth aspect is the cooling device 101 according to any one aspect of (1) to (3), in which, on at least one of the surface of the bottom plate 112 facing a side of the flow path F and a surface of the base 10 facing the side of the flow path F, a slope portion 116 extending in a direction apart from the other surface as being apart from the introduction port 17 to both sides in the first direction d1 may be provided.

With the above-described configuration, the slope portion 116 is provided, so that the pressure loss of the refrigerant in the direction apart from the introduction port 17 is reduced. Therefore, the flow of the refrigerant is further smoothed, so that it is possible to further increase the cooling effect on each semiconductor component 20.

(6) A cooling device 1, 101 according to a sixth aspect is the cooling device 1, 101 according to any one aspect of (1) to (5), in which the cooling body may be a plurality of fins 11 that protrude from the bottom plate 12, 112 toward the base 10, extend in the first direction d1, and are arranged at intervals in the second direction d2 orthogonal to the first direction d1.

With the above-described configuration, it is possible to efficiently cool the respective semiconductor components 20 using the fins 11 as the cooling body.

(7) A cooling device 1 according to a seventh aspect is the cooling device 1 according to any one aspect of (1) to (5), in which the cooling body may be a plurality of pins 111 each having a rod shape protruding from the bottom plate 12 toward the side of the base 10 and arranged at intervals from each other.

With the above configuration, since the cooling body is the pin 111, the surface area is increased as compared to the fin 11. As a result, the heat exchange amount between the refrigerant and the cooling body, so that it is possible to further efficiently cool each of the semiconductor components 20.

### INDUSTRIAL APPLICABILITY

It is possible to provide a cooling device that exhibits a higher cooling effect.

### Reference Signs List

1: Cooling device
2: Substrate
10: Base
11: Fin
12: Bottom plate
13: Rear surface
14: Side wall
15: Bottom plate main body
16: Thick wall portion
17: Introduction port
20: Semiconductor component
21: Substrate main body
22: Copper pattern
23: Bonding material
24: Bonding material
101: Cooling device
111: Pin
112: Bottom plate
115: Bottom plate main body
116: Slope portion
117: Opening portion
116a: Inclined surface
21a: First semiconductor component
21b: Second semiconductor component
d1: First direction
d2: Second direction
F: Flow path

1-7. (canceled)

8. A cooling device that cools a plurality of semiconductor components, which are mounted on a front surface of a substrate and are arranged in a first direction, the cooling device comprising:
a base attached to a rear surface of the substrate;
a bottom plate disposed apart from the base to form a flow path through which a refrigerant flows between the bottom plate and the base; and
a cooling body disposed in the flow path, wherein
an introduction port, through which the refrigerant is guided into the flow path from a direction facing the rear surface, is formed in a central portion of the bottom plate in the first direction,
a flow path cross sectional area of the flow path at the introduction port is smaller than flow path cross sectional areas on both sides of the flow path in the first direction.,
the introduction port extends in a second direction orthogonal to the first direction,
the introduction port is formed of a plurality of opening portions arranged at intervals in the second direction, and
the opening portion has any of a rectangular shape, a polygonal shape, or an elliptical shape.

9. The cooling device according to claim 8, wherein
in a region, which is at least one of a surface of the bottom plate facing a side of the flow path and a surface of the base facing the side of the flow path and includes the introduction port, a thick wall portion protruding from the bottom plate toward a side of the base is provided.

10. The cooling device according to claim 8, wherein
on at least one of a surface of the bottom plate facing a side of the flow path and a surface of the base facing the side of the flow path, a slope portion extending in a direction apart from the other surface as being apart from the introduction port to both sides in the first direction is provided.

11. The cooling device according to claim 8, wherein
the cooling body is a plurality of fins that protrude from the base toward the bottom plate, extend in the first direction, and are arranged at intervals in a second direction orthogonal to the first direction.

12. The cooling device according to claim 8, wherein
the cooling body is a plurality of pins each having a rod shape protruding from the base toward a side of the bottom plate and arranged at intervals from each other.
